(19) United States
(12) Patent Application Publication
(10) Pub. No.: US 2018/0175324 A1
(43) Pub. Date: Jun. 21, 2018

(54) DISPLAY DEVICE HAVING A PROTECTION LAYER

(71) Applicant: Japan Display Inc., Tokyo (JP)

(72) Inventor: Takahiro FUJIOKA, Tokyo (JP)

(21) Appl. No.: 15/830,110

(22) Filed: Dec. 4, 2017

(30) Foreign Application Priority Data
Dec. 15, 2016 (JP) 2016-242994

(51) Int. Cl. H01L 51/52; H01L 27/32; H01L 51/00; H01L 51/56

(52) U.S. Cl. CPC H01L 51/5253; H01L 27/3276; H01L 51/0097; H01L 2227/326; H01L 51/56; H01L 51/003; H01L 2251/5338; H01L 51/5281

(57) ABSTRACT

A display device in an embodiment according to the present invention include a substrate including a display region arranged with a plurality of pixels, and a terminal region arranged with a plurality of connection terminals on a first surface of the substrate, a plurality of wirings between the terminal region and the display region and transmitting a signal for controlling light emission of the plurality of pixels, a polarization plate covering the display region, an oil repellent layer along an end part of the polarization plate, and a first protection layer covering the plurality of wirings for preventing exposure of the first surface of the substrate, the first protection layer arranged on the outer side of the polarization plate in a planar view in contact with an end part of the polarization plate.

### CROSS REFERENCE TO RELATED APPLICATIONS

This application is based upon and claims the benefit of priority from the prior Japanese Patent Application No. 2016-242994, filed on Dec. 15, 2016, the entire contents of which are incorporated herein by reference.

### FIELD

An embodiment of the present invention is related to a display device. An embodiment of the present invention is related to a structure of a protection layer for protecting a surface of a display device.

### BACKGROUND

An organic electroluminescence (referred to as “organic EL” herein) display device is arranged with a light emitting element in each of a plurality of pixels, and an image is displayed by individually controlling light emission of the light emitting elements. A light emitting element has a structure in which a layer including an organic EL material (also referred to as “light emitting layer” herein) is sandwiched between a pair of electrodes which are distinguished as an anode and the other as a cathode. Electrons and holes are recombining in the light emitting layer when the electrons are injected into the light emitting layer from the cathode and the holes are injected from the anode. Light emitting molecules in the light emitting layer are excited by the surplus energy emitted thereby, and then de-excited to emit light.

In the organic EL display device, the anode of each light emitting elements is arranged as a pixel electrode for each pixel, and the cathode is arranged as a common electrode across which a common potential is applied across a plurality of pixels. The organic EL display device controls the light emission of a pixel by applying the potential of the pixel electrode for each pixel with respect to the potential of the common electrode.

In recent years, a bendable flexible display device has been actively developed. For example, Japanese Unexamined Patent Application Publication No. 2011-209405 discloses a display device including a bendable substrate, a pixel array part in which pixels including an electro-optical element are arranged on a substrate, an end part of the substrate on which at least one side of a periphery of the pixel array part above the substrate is bent, a periphery circuit part which arranged at the substrate end part and which drives each pixel of the pixel array part, and a pad part arranged above the same substrate end part as the periphery circuit part and which electrically connects the periphery circuit part and a substrate outer part.

### SUMMARY

A display device in an embodiment according to the present invention include a substrate including a display region arranged with a plurality of pixels, and a terminal region arranged with a plurality of connection terminals on a first surface of the substrate, a plurality of wirings between the terminal region and the display region and transmitting a signal for controlling light emission of the plurality of pixels, a polarization plate covering the display region, an oil repellent layer along an end part of the polarization plate, and a first protection layer covering the plurality of wirings for preventing exposure of the first surface of the substrate, the first protection layer arranged on the outer side of the polarization plate in a planar view in contact with an end part of the polarization plate.

### BRIEF DESCRIPTION OF DRAWINGS

FIG. 1 is a perspective view diagram for explaining a schematic structure of a display device related to one embodiment of the present invention;

FIG. 2 is a planar view diagram for explaining a structure of a display device related to one embodiment of the present invention;

FIG. 3A is a cross-sectional diagram for explaining a structure of a display device related to one embodiment of the present invention;

FIG. 3B is a cross-sectional diagram for explaining a structure of a display device related to one embodiment of the present invention;

FIG. 3C is a cross-sectional diagram for explaining a structure of a display device related to one embodiment of the present invention;

FIG. 4A is a cross-sectional diagram for explaining a manufacturing method of a display device related to one embodiment of the present invention;

FIG. 4B is a cross-sectional diagram for explaining a manufacturing method of a display device related to one embodiment of the present invention;

FIG. 4C is a cross-sectional diagram for explaining a manufacturing method of a display device related to one embodiment of the present invention;

FIG. 5 is a cross-sectional diagram for explaining a structure of a display device related to one embodiment of the present invention;

FIG. 6A is a cross-sectional diagram for explaining a manufacturing method of a display device related to one embodiment of the present invention;

FIG. 6B is a cross-sectional diagram for explaining a manufacturing method of a display device related to one embodiment of the present invention;

FIG. 6C is a cross-sectional diagram for explaining a manufacturing method of a display device related to one embodiment of the present invention; and

FIG. 6D is a cross-sectional diagram for explaining a manufacturing method of a display device related to one embodiment of the present invention.

### DESCRIPTION OF EMBODIMENTS

The display device related to some of embodiments of the present invention are explained in detail below while referring to the diagrams. Furthermore, it is possible to perform the present invention using various different forms, and the present invention should not be limited to the embodiments exemplified herein. In the embodiments described following, the same reference symbols are attached to the same structural elements. In addition, the dimensions in the diagrams are different to their ratios in order to better clarify explanation, and therefore parts of the structure may be omitted from the drawings.

For example, there is no disclosure in the display device described in Japanese Laid Open Patent Publication No. 2011-209405 of a structure in which a polarization plate is arranged in a pixel array part or a protection layer for protecting a wiring part is arranged.

A protection resin in order to protect wiring on a substrate is coated on a bent part arranged on display device having flexibility. This protection resin needs to be coated so that the substrate is not exposed in order to prevent damage when handling during the manufacturing process and during use. When the protection resin is formed, a polarization plate is arranged in a display region. In this process, if the protection resin runs over the polarization plate, there is a possibility of a decrease in display quality, or defects are caused at the time of lamination of a cover glass in the next process.

In order to prevent such a problem, a measure for coating the protection resin while leaving a separator of the polarization plate is considered. However, with peeling of a separator, there is a danger that damage such as peeling may be applied to an end part of the protection resin.

In the embodiments of the present invention described below, a technique is disclosed in which a protection resin for protecting wiring on a substrate is coated without running over a polarization plate.

### First Embodiment

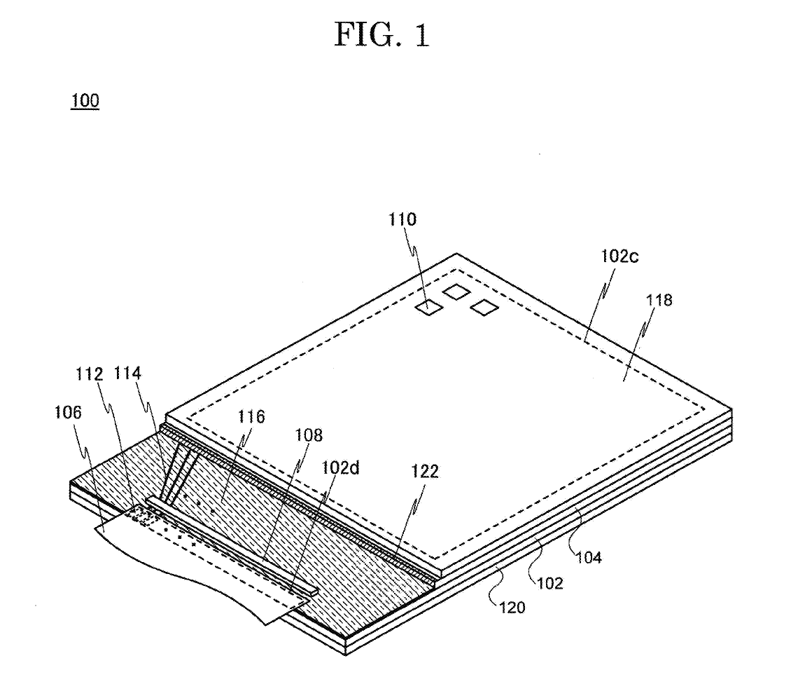

FIG. 1 is a perspective view for explaining a schematic structure of a display device 100 according to the present embodiment. The display device 100 according to the present embodiment includes a first substrate 102, a polarization plate 104, a wiring substrate 106 and a driver IC 108.

The first substrate 102 is arranged with a display region 102c and a terminal region 102d. The display region 102c and the terminal region 102d are arranged on the same surface of the first substrate 102. A plurality of pixels 110 are arranged in the display region 102c. The terminal region 102d is arranged at the end part of the first substrate 102 and on the outer side of the polarization plate 104. The first substrate 102 functions as a support for the plurality of pixels 110 and a plurality of connection terminals 112. A flexible substrate can be used as the first substrate 102.

Each of the plurality of pixels 110 includes a pixel electrode. The pixel electrode includes a metal layer and which has a light reflecting surface. The polarization plate 104 prevents external light incident on the display region 102c from being reflected by the pixel electrode and being emitted to the side of a viewer. That is, the polarization plate 104 is arranged to suppress deterioration of visibility due to reflection of exterior light in the display region 102c. The polarization plate 104 is arranged on the first substrate 102 to cover the display region 102c. Furthermore, although the polarization plate 104 is shown as being arranged on the first substrate in the present embodiment, the polarization plate is not absolutely necessary and may be replaced by other members. For example, the polarization plate 104 may be replaced by a transparent substrate or the like. The transparent substrate may be a plate shaped substrate or a film shaped sheet.

A part in the wiring substrate 106 which is connected to a connection terminal 112 is arranged to overlap the terminal region 102d. The wiring substrate 106 is connected to the plurality of connection terminals 112 arranged in the terminal region 102d. A video signal and a clock signal for controlling light emission of the plurality of pixels 110 are input to the plurality of connection terminals 112 via the wiring substrate 106.

The driver IC 108 is arranged on the outer side of the polarization plate 104 on the first surface (surface on which the display region 102c and terminal region 102d are arranged) of the first substrate 102. A signal from the wiring substrate 106 may be input to the driver IC 108 via the plurality of connection terminals 112 and an output from the driver IC 108 may be transmitted to the plurality of pixels 110 by the plurality of wirings 114.

In the first surface of the first substrate 102, a first protection layer 116 is arranged to cover the plurality of wirings 114 in a region where the polarization plate 104 is not arranged. In addition, on the first surface of the first substrate 102, an oil repellent layer 122 is arranged along an end part of the polarization plate 104. In the display device 100, a second protection layer 112 is arranged on an upper surface of the polarization plate 104, and a third protection layer 120 is arranged on a surface of the first substrate 102 opposite to the first surface. Details of these members are described later.

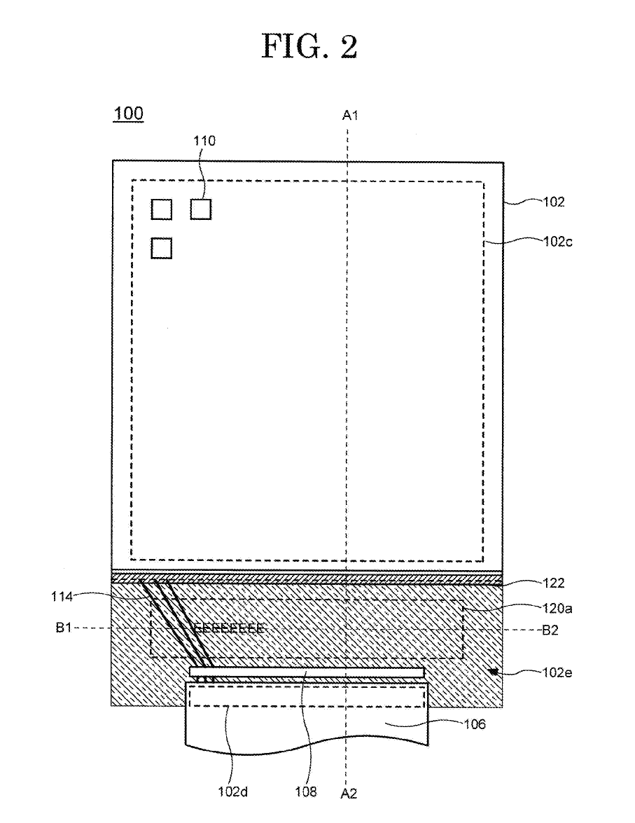

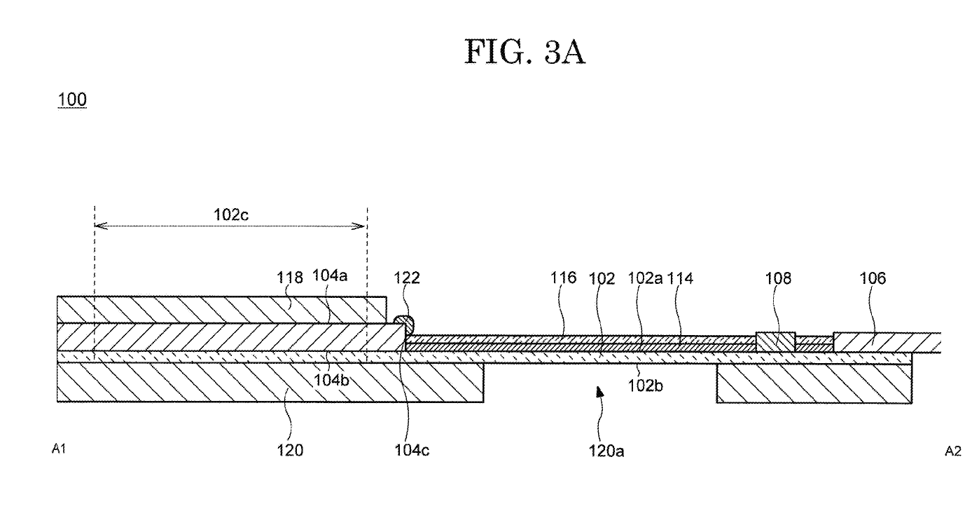

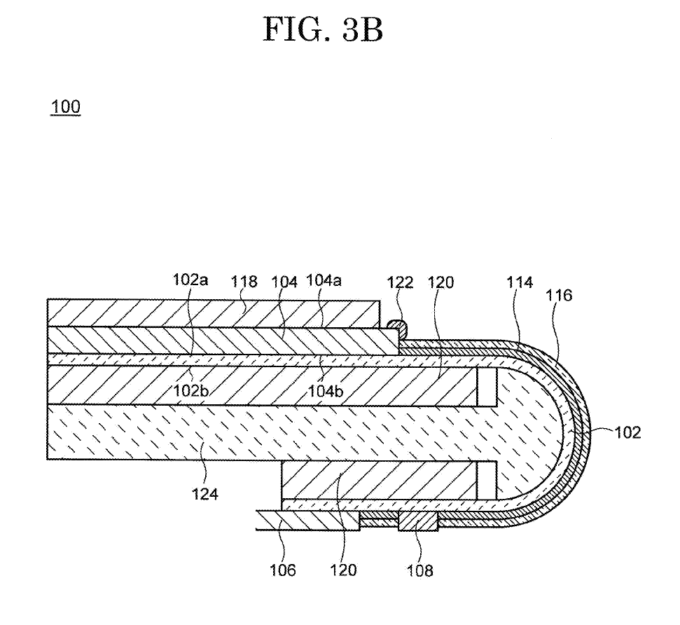

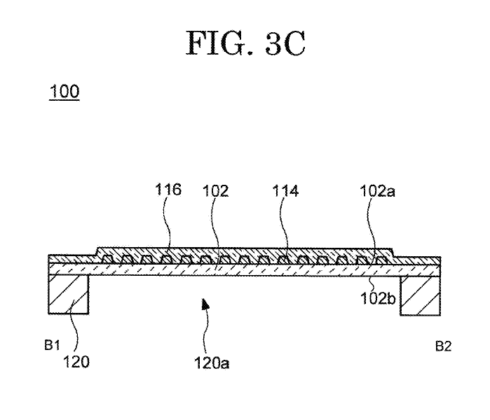

FIG. 2 is a planar view diagram for explaining a structure of the display device 100 according to the present embodiment. FIG. 3A is a cross-sectional diagram for explaining a structure of the display device 100 according to the present embodiment, and shows a cross-section along the line A1-A2 in FIG. 2. FIG. 3B is a cross-sectional diagram for explaining a structure of the display device 100 according to the present embodiment, and shows an aspect in which the display device 100 shown in FIG. 3A is folded. FIG. 3C is a cross-sectional diagram for explaining a structure of the display device 100 according to the present embodiment and shows a cross-section along the line B1-B2 in FIG. 2.

As is shown in FIG. 2, FIG. 3A and FIG. 3B, the display device 100 according to the present embodiment includes, on a first surface 105a of the first substrate 102, a display region 102c, a plurality of wirings 114, a polarization plate 104, a terminal region 102d, a driver IC 108, a first protection layer 116, a second protection layer 118 and an oil repellent layer 122, and a third protection layer 120 is arranged on the second surface 102b. The terminal region 102d is connected to the wiring substrate 106. Furthermore, the second surface 102b of the first substrate 102 is a surface opposite to the first surface 102a.

The first substrate 102 has a bent region 102e between the display region 102c and the terminal region 102d. As is shown in FIG. 3B, the display device 100 according to the present embodiment is bent in the bent region 102e. In the case of bending the display device 100, one end of a spacer 124 which is formed into a curved surface is arranged on a lower surface of the third protection layer 120, and the first substrate 102 may be bent along this curved surface. The third protection layer 120 may be arranged with a slit 120a at a position corresponding to one end of the spacer 124. As a result, the first substrate 102 is bent in contact with the curved surface arranged at one end of the spacer 124 and the curvature can be kept constant. By bending the substrate 102 so that a region on which the driver IC 108 and the wiring substrate 106 are mounted is arranged on the rear side of the display region 102c, it is possible to narrow the frame width of the display device 100. The third protection layer 120 is arranged with a slit 120a in a region overlapping with the bent region 102e.

In the present embodiment, the first substrate 102 having a flexibility. A resin material is used as a substrate having flexibility. It is preferred to use a polymer material containing an imide bond as a repeating unit, for example, polyimide as the resin material. Specifically, a film substrate obtained by molding polyimide into a sheet shape is used as the substrate.

A plurality of pixels 110 are arranged in the display region 102c. Although not shown in the diagram, each of the plurality of pixels 110 has a pixel circuit. The pixel circuit includes a light emitting element. The light emitting element 128 has a layer structure in which at least a pixel electrode, a light emitting layer and a common electrode are stacked in this order from the first substrate 102 side. A self-light-emitting type light emitting element can be used as the light emitting element. For example, an organic EL light emitting element can be used as the self-light emitting type light emitting element.

The pixel electrode is arranged in each of the plurality of pixels 110. It is preferred to include a metal layer having a high reflectance as the material of the pixel electrode in order to reflect the light generated in the light emitting layer to the common electrode side. Silver (Ag) can be used as the metal layer having high reflectivity for example.

A common electrode 134 is arranged across the plurality of pixels 110. A light transmitting conducting layer is preferred as a material of the common electrode in order to transmit light generated in the light emitting layer. For example, ITO (indium oxide doped with tin oxide), IZO (indium oxide and zinc oxide), or the like can be used as a material of the common electrode. Alternatively, a metal layer having a thickness sufficient to transmit emitted light may be used as the common electrode. Furthermore, the common electrode may be formed individually for each pixel electrode.

The light emitting layer is arranged sandwiched between the pixel electrode and the common electrode. An organic EL material which emits light when an electric current is supplied can be used as the material of the light emitting layer. A low molecular type or high molecular type organic material can be used as the organic EL material. In the case where a low molecular weight organic material is used, in addition to a light emitting organic material, a light emitting layer may contain a hole injecting layer, an electron injecting layer, a hole transporting layer, an electron transporting layer or the like so as to sandwich a light emitting organic material.

The terminal region 102d is arranged at an end part of the first surface 102a of the first substrate 102 and on the outer side the polarization plate 104, and a plurality of connection terminals 112 are arranged. A wiring substrate 106 is arranged overlapping the terminal region 102d. The wiring substrate 106 is connected to the plurality of connection terminals 112 and connects the display device 100 to devices that output video signals or a power supply and the like.

A plurality of wirings 114 are arranged between the terminal region 102d and the display region 102c in the first surface 102a of the first substrate 102. That is, the plurality of wirings 114 are arranged to pass through the bent region 102e. The plurality of wirings 114 are arranged to transmit a signal for controlling the light emission of the plurality of pixels 110. That is, the plurality of wirings 114 are wirings for transmitting a video signal for controlling the light emission of the plurality of pixels 110, and for transmitting a video signal and a clock signal input to the plurality of terminal electrodes 112 arranged in the terminal region 102d.

The polarization plate 104 is arranged to suppress deterioration of visibility of the display device 100 by reflecting external light incident on the display device 100 by a pixel electrode arranged in each of the plurality of pixels 110. The polarization plate 104 is arranged on the first surface 102a side of the first substrate 102 to cover the display region 102c.

The polarization plate 104 includes at least a polarization element. A film formed by stretching polyvinyl alcohol (PVA) is mainly used as the polarization element. The polarization plate 104 may further include a protection layer, a retardation plate and a separator and the like. The protection layer is arranged on both surfaces of the polarization element. In this way, the strength of the polarization plate 104 can be secured. A film of triacetylcellulose (TAC) or the like is mainly used as the protection layer. For example, the phase difference plate imparts a phase difference of quarter wavelength to the transmitted light. The separator is arranged on the outermost side on both surfaces of the polarization plate 104. A film of polyethylene terephthalate (PET) or the like is mainly used as the separator.

Here, for the sake of convenience of subsequent explanation, the surface on the first substrate 102 side among the two opposing surfaces of the polarization plate 104 is called the second surface 104b of the polarization plate 104, and the surface opposing the second surface 104b of the polarization plate 104 is called the first surface 104a. In addition, the surface between the first surface 104a and the second surface 104b of the polarization plate 104 is called a side surface 104c.

The first protection layer 116 is arranged to protect the plurality of wirings 114 and to prevent damage to the first substrate 102 during the manufacturing process of the display device 100 and in handling during use. The plurality of wirings 114 are arranged on the first surface 102a of the first substrate 102. The first protection layer 116 is arranged on the first surface 102a side of the first substrate 102. The first protection layer 116 covers the plurality of wirings 114 and prevents exposure of the first surface 102a of the first substrate 102. Here, as described above, the display region 102c above the first surface 102a of the first substrate 102 is not exposed since it is covered by the polarization plate 104. As a result, the first protection layer 116 is required only to be able to prevent exposure of a region not covered by the polarization plate 104 on the first surface 102a of the first substrate 102.

The first protection layer 116 is arranged on the outer side of the polarization plate 104 in a planar view. That is, the first protection layer 116 does not overlap with the polarization plate 104 and prevents exposure of the first surface 102a of the first substrate 102 in a planar view. In other words, in a planar view, the first protection layer 116 is in contact with an end part of the polarization plate 104.

Here, when the first protection layer 116 overlaps with the polarization plate 104 and also overlaps with a part of the display region 102c, display quality deteriorates. Furthermore, in this case, due to unevenness caused by the first protection layer 116, it becomes difficult to favorably attach a second protection layer 118 described later to the polarization plate 104, and the yield of the display device 100 decreases.

Furthermore, in the present embodiment, the first protection layer 116 does not overlap with the driver IC 108 and the wiring substrate 106, but is arranged on the outer side the driver IC 108 and the wiring substrate 106. However, the present invention is not limited to such an aspect and the first protection layer 116 may cover at least one of the driver IC 108 and the wiring substrate 106.

On the other hand, the first protection layer 116 is in contact with a side surface 104c of the polarization plate 104 in a cross-sectional view. In addition, the first protection layer 116 is not in contact with the first surface 104a of the polarization plate 104 in a cross-sectional view. This means that, as described above, the first protection layer 116 does not overlap with the polarization plate 104 in a planar view.

As is described in detail later, an oil repellent layer 122 is arranged along an end part of the polarization plate 104, whereby the first protection layer 116 is prevented from entering the first surface 104a of the polarization plate 104.

An organic resin material can be used as the material of the first protection layer 116. For example, an acrylic resin may be used as the material of the first protection layer 116. The film thickness of the first protection layer 116 is preferred to be 40 μm or more and 200 μm or less. If the film thickness of the first protection layer 116 is smaller than this range, it is insufficient to protect the first substrate 102 and the plurality of wirings 114 in the manufacturing process and handling during use. In addition, when the film thickness of the first protection layer 116 is larger than this range, the display device 100 does not have sufficient flexibility. The film thickness of the first protection layer 116 can be 100 μm for example.

The second protection layer 118 is arranged above the polarization plate 104. A material having high transparency, high flatness, and scratch resistance is preferred for the second protection layer 118. The second protection layer 118 may be a plate shaped substrate or a film shaped (or sheet shaped). Specifically, for example, a glass base substrate, an acrylic resin or the like can be used as the second protection layer 118.

The third protection layer 120 is arranged above the second surface 102b side of the first substrate 102. The third protection layer 120 is a film shaped sheet for protecting the display device 100. An organic resin material can be used as the material of the third protection layer 120. For example, polyimide resin, acrylic resin, epoxy resin, polyethylene terephthalate or silicone resin can be used as the organic resin material. A metal material may be used as the material of the third protection layer 120. For example, stainless steel, copper or the like can be used as the metal material. The slit 120a is arranged for opening the third protection layer 120 and for increasing flexibility in the bent region 102e of the display device 100.

The oil repellent layer 122 is arranged along the end part of the polarization plate 104. The oil repellent layer 122 is arranged on the outer side of the display region 102c in a planar view. In the present embodiment, the oil repellent layer 122 is arranged in the vicinity of a side between the first surface 104a and the side surface 104c of the polarization plate 104. In other words, the oil repellent layer 122 is arranged from the first surface 104a of the polarization plate 104 to the side surface. Here, the oil repellent layer 122 is arranged on the outer side of the display region 102c on the first surface 104a of the polarization plate 104, and is arranged in one part of the side surface 104c of the polarization plate 104. That is, the end part of the oil repellent layer 122 is arranged on the outer side of the display region 120c above the first surface 102a of the first substrate 102 and is also arranged within the side surface 104c of the polarization plate 104. In this way, the oil repellent layer 122 acts to prevent the first protection layer 116 from running over the side surface 104c of the polarization plate 104 and entering the first surface 104a of the polarization plate 104 due to oil repellency. In this way, the first protection layer 116 is prevented from being attached to the polarization plate 104, and a deterioration in display quality can be prevented. In addition, when the second protection layer 118 is arranged above the polarization plate 104, the flatness of an underlying surface (upper surface of the polarization plate 104) is secured. Since the oil repellent layer 122 is arranged on the outer side of the display region 102c in the first surface 104a of the polarization plate 104, the oil repellent layer 122 does not deteriorate display quality, and the second protection layer 118 can be arranged to cover the entire display region 102c.

Furthermore, oil repellency is a term meaning the property of repelling oil, that is, an oily liquid, and the oil repellent layer 122 has similar properties. A material having a property of repelling an oily liquid is preferred as the material of the oil repellent layer 122. For example, either a silicone resin or a fluorine resin are examples of a specific material of the oil repellent layer 122.

According to the structure of the display device 100 according to the present embodiment, the first protection layer 116 can prevent the first surface 102a of the first substrate 102 from being exposed, and can prevent the first protection layer 116 from entering the first surface 104a of the polarization plate 104. That is, damage to the first substrate 102 can be effectively prevented, and a highly reliable display device 100 can be provided. Furthermore, since the first protection layer 116 does not enter into the first surface 104a of the polarization plate 104, the first protection layer 116 does not deteriorate visibility. Furthermore, adhesion of the second protection layer 118 arranged above the polarization plate 104 is improved, and a highly reliable display device 100 can be provided.

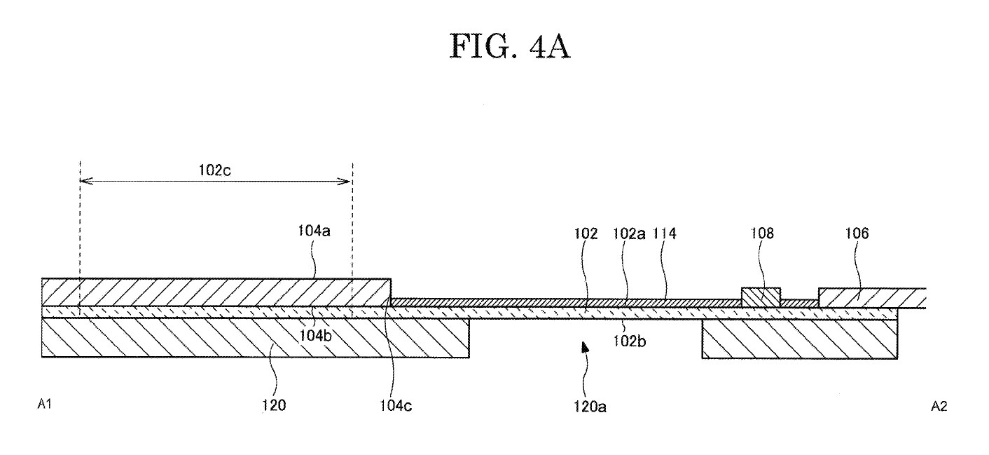

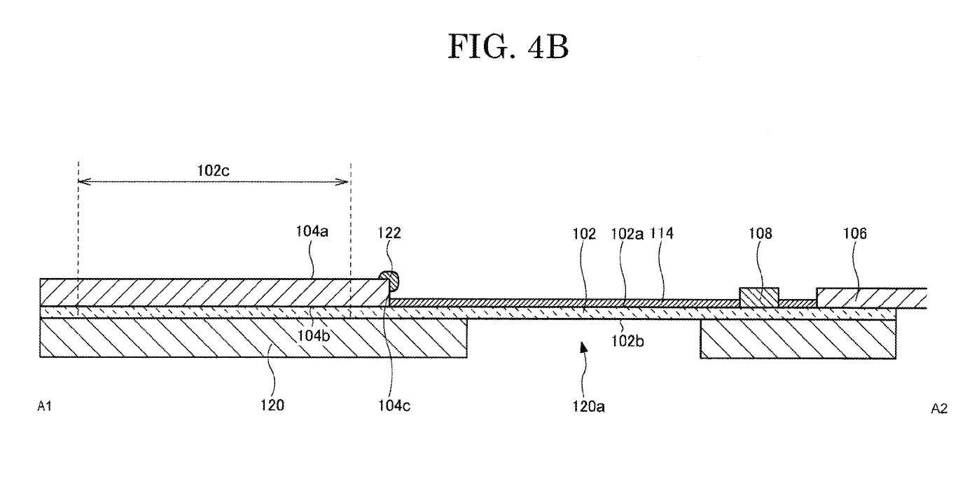

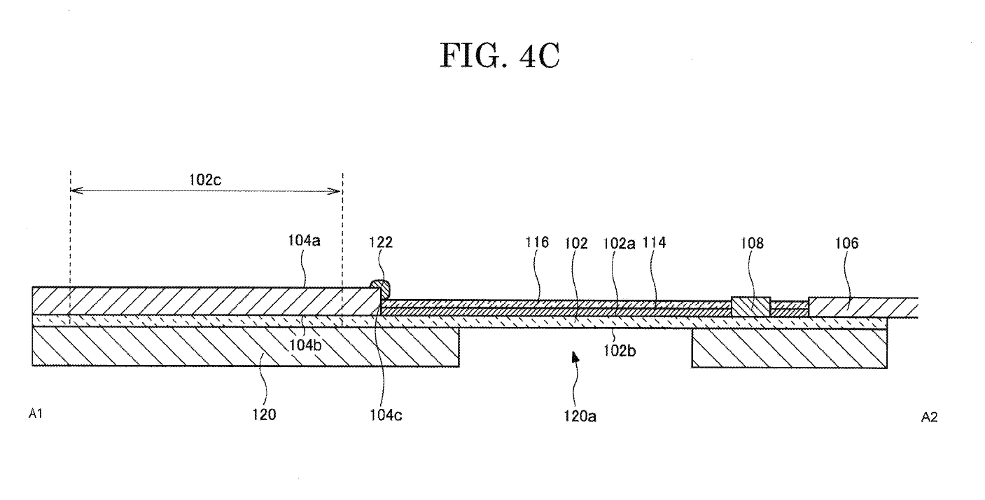

Next, a method of manufacturing the display device 100 according to the present embodiment is explained in detail while referring to the drawings. FIG. 4A to FIG. 4C are cross-sectional diagrams for explaining a method of manufacturing the display device 100 according to the present embodiment. Here, particularly, a method of forming the first protection layer 116 is mainly explained.

FIG. 4A is a diagram in which a plurality of pixels 110, a plurality of connection terminals 112 and a plurality of wirings 114 are formed on a first surface 102a of a first substrate 102, a third protection layer 120 is formed on a second surface 102b of the first substrate 102, a polarization plate 104 is formed on the first surface 102a side of the first substrate 102, and a driver IC 108 and a wiring substrate 106 are mounted on the first surface 102a side of the first substrate 102.

Next, as is shown in FIG. 4B, an oil repellent layer 122 is formed on the first surface 102a of the first substrate 102. The oil repellent layer 122 is formed along an end part of the polarization plate 104. In the present embodiment, the oil repellent layer 122 is formed in the vicinity of a side between the first surface 104a and the side surface 104c of the polarization plate 104. Here, the oil repellent layer 122 is formed on the outer side of the display region 102c on the first surface 104a of the polarization plate 104, and is formed in one part of the side surface 104c of the polarization plate 104.

Next, as is shown in FIG. 4C, a first protection layer 116 is formed on the first surface 102a side of the first substrate 102. The first protection layer 116 is formed so as to cover an exposed region on the first surface 102a of the first substrate 102. Here, the display region 102c above the first surface 102a of the first substrate 102 is not exposed since it is covered by the polarization plate 104. As a result, the first protection layer 116 may be formed on the first surface 102a of the first substrate 102 so as to prevent exposure of a region on the outer side of the polarization plate 104.

An organic resin material can be used as the material of the first protection layer 116. The organic resin material is, for example, an acrylic resin. The film thickness of the first protection layer 116 is preferred to be 40 μm or more and 200 μm or less. An inkjet method, a coating method using a dispenser or the like can be used as a method of forming the first protection layer 116. As a result, the first protection layer 116 is selectively formed on the first surface 102a of the first substrate 102 on the outer side of the polarization plate 104.

An oil repellent layer 122 is formed in the vicinity of an end part of the polarization plate 104. Since the oil repellent layer 122 has oil repellency, when the first protection layer 116 is coated, it is repelled by the oil repellent layer 122, and the first protection layer 116 is prevented from running on the side surface 104c of the polarization plate 104 and further becoming attached to the first surface 104a of the polarization plate 104.

A method of a display device without arranging the oil repellent layer 122 has the following problems. In order to ensure that the first surface 102a of the first substrate 102 is covered with the first protection layer 116, the first protection layer 116 runs over the side surface 104c of the polarization plate 104, and further enters into the first surface 104a of the polarization plate 104. In this way, problems such as deterioration of display quality and failure to sufficiently attach a protection layer to the polarization plate 104 occur. On the other hand, when attempting to prevent the first protection layer 116 from entering the first surface 104a of the polarization plate 104 as much as possible, the vicinity of an end part of the polarization plate 104 on the first surface 102a of the first substrate 102 is difficult to sufficiently cover. In this way, a problem occurs whereby the first substrate 102 is likely to be damaged with the uncovered region as a starting point.

According to the manufacturing method of the display device 100 according to the present embodiment, the first protection layer 116 prevents the first surface 102a of the first substrate 102 from being exposed, and the first protection layer 116 is prevented from entering the first surface 102a of the polarization plate 104. That is, damage to the first substrate 102 can be effectively prevented and a highly reliable display device 100 can be provided. Furthermore, since the first protection layer 116 does not enter into the first surface 104a of the polarization plate 104, the first protection layer 116 does not deteriorate visibility. Furthermore, adhesion of the second protection layer 118 arranged above the polarization plate 104 is improved and a highly reliable display device 100 can be provided.

Furthermore, in the present embodiment, the first protection layer 116 does not cover the driver IC 108 and the wiring substrate 106, but is arranged on the outer side of the driver IC 108 and the wiring substrate 106. However, the present invention is not limited to such an aspect and the first protection layer 116 may be formed so as to cover at least one of the driver IC 108 and the wiring substrate 106.

Next, the second protection layer 118 is arranged on the first surface 104a side of the polarization plate 104 to complete the display device 100 shown in FIG. 3A.

According to the method for manufacturing the display device 100 according to the present embodiment, by providing the oil repellent layer 122 along the end part of the polarization plate 104, the display device 100 with high reliability is easily provided without deteriorating display quality.

### Second Embodiment

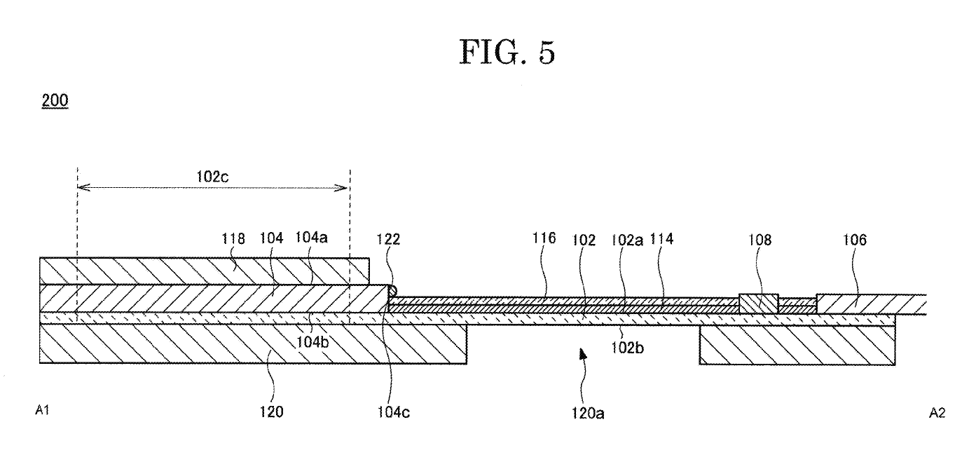

The structure of a display device 200 according to the present embodiment is explained in detail while referring to the drawings. Furthermore, the schematic structure of the display device 200 according to the present embodiment is the same as that of the display device 100 according to the first embodiment. FIG. 5 is a cross-sectional diagram for explaining the structure of the display device 200 according to the present embodiment.

The display device 200 according to the present embodiment is different from the display device 100 according to the first embodiment in the arrangement of the oil repellent layer 122. In the present embodiment, the oil repellent layer 122 is not arranged above the first surface 104a of the polarization plate 104, but is arranged only on the side surface 104c of the polarization plate 104.

According to the structure of the display device 200 according to the present embodiment which can achieve the same effects as that of the display device 100 according to the first embodiment, it is possible to prevent exposure of the first surface 102a of the first substrate by the first protection layer 116 and it is possible to prevent the first protection layer 116 from entering the first surface 102a of the polarization plate 104. That is, it is possible to effectively prevent damage to the first substrate 102, and a highly reliable display device 200 can be provided. Furthermore, since the first protection layer 116 does not enter into the first surface 104a of the polarization plate 104, the first protection layer 116 does not deteriorate visibility. Furthermore, adhesion of the second protection layer 118 arranged above the polarization plate 104 is improved, and a highly reliable display device 200 can be provided.

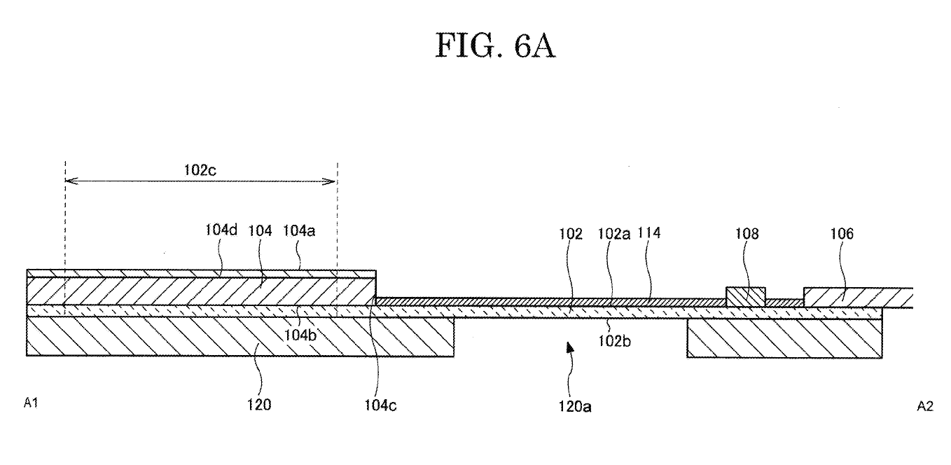

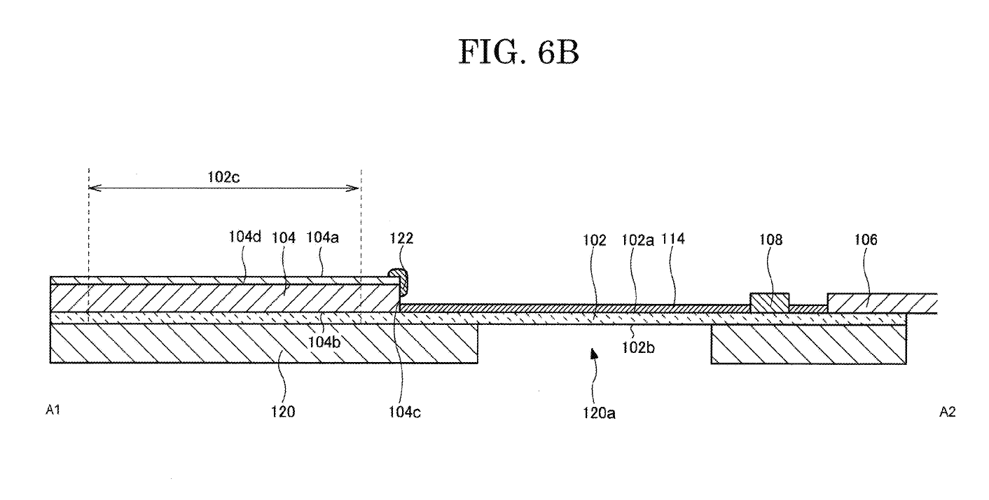

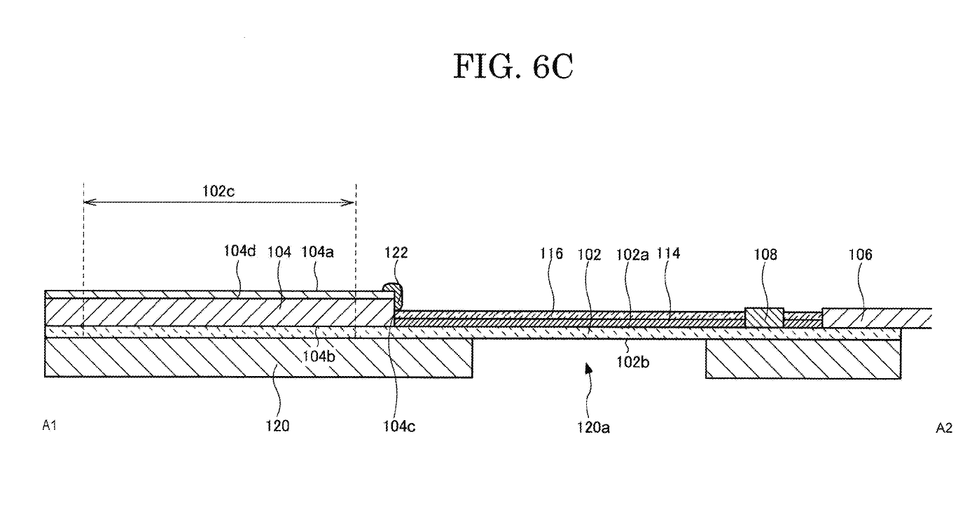

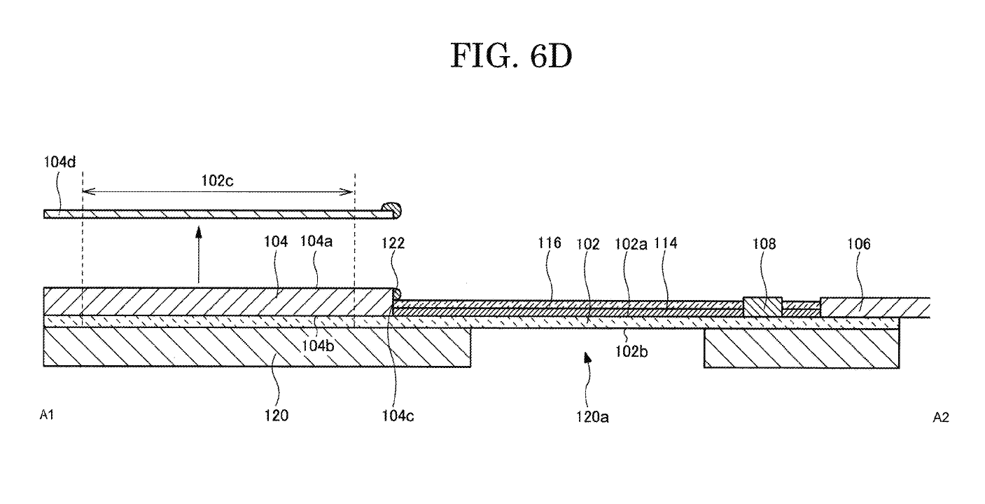

Next, a manufacturing method of the display device 200 according to the present embodiment is explained in detail while referring to the drawings. FIG. 6A to FIG. 6D are cross-sectional diagram for explaining a method of manufacturing the display device 200 according to the present embodiment. Here, particularly, a method of forming the first protection layer 116 is mainly explained.

FIG. 6A is a diagram in which a plurality of pixels 110, a plurality of connection terminals 112 and a plurality of wirings 114 are formed on a first surface 102a of a first substrate 102, a third protection layer 120 is formed on a second surface 102b of the first substrate 102, a polarization plate 104 is formed on the first surface 102a side of the first substrate 102 and a driver IC 108 and a wiring substrate 106 are mounted on the first surface 102a side of the first substrate 102. At this stage, the polarization plate 104 has a separator 104d on the first surface 104a side.

Next, an oil repellent layer 122 is formed as is shown in FIG. 6B. The oil repellent layer 122 is formed along an end part of the polarization plate 104. In the present embodiment, the oil repellent layer 122 is formed in the vicinity of a side between the first surface 104a and the side surface 104c of the polarization plate 104. Here, the oil repellent layer 122 is formed on the outer side of the display region 102c on the first surface 104a of the polarization plate 104 including the separator 104d, and is formed on a part of the side surface 104c of the polarization plate 104.

Next, as is shown in FIG. 6C, a first protection layer 116 is formed on the first surface 102a side of the first substrate 102. In the step shown in FIG. 6B, the first protection layer 116 is formed so as to cover the exposed region on the first surface 102a of the first substrate 102.

Here, the display region 102c on the first surface 102a of the first substrate 102 is not exposed since it is covered by the polarization plate 104. As a result, the first protection layer 116 is only required to be able to prevent exposure of a region not covered by the polarization plate 104 on the first surface 102a of the first substrate 102. For the material of the first protection layer 116 and the method of forming the first protection layer 116, the materials and methods described in the first embodiment can be respectively used. In this way, the first protection layer 116 can be selectively formed on the outer side of the polarization plate 104 on the first surface 102a of the first substrate 102.

Here, due to the oil repellent effects of the oil repellent layer 122 formed in the vicinity of the end part of the polarization plate 104, it is possible to prevent the first protection layer 116 from running on the side surface 104c of the polarization plate 104, and further prevent it entering the first surface 104a of the polarization plate 104. Furthermore, in the present embodiment, the first protection layer 116 is not covered by the driver IC 108 and the wiring substrate 106, but is arranged on the outer side of the driver IC 108 and the wiring substrate 106. However, the present invention is not limited to such an aspect and the first protection layer 116 may be formed so as to cover at least one of the driver IC 108 and the wiring substrate 106.

Next, as is shown in FIG. 6D, the separator 104d is peeled off. In this way, the oil repellent layer 122 does not remain on the first surface 104a side of the polarization plate 104, and the oil repellent layer 122 remains only on the side surface 104c of the polarization plate 104.

In the present embodiment, an aspect in which the separator 104d is peeled off after forming the first protection layer 116 as explained. However, this sequence may be reversed. That is, the first protection layer 116 may be formed after peeling off the separator 104d.

A method of a display device which is not arranged with the oil repellent layer 122 described above has the following problems. In order to reliably cover the first surface 102a of the first substrate 102 with the first protection layer 116, the first protection layer 116 runs over the side surface 104c of the polarization plate 104 including the separator 104d, and furthermore is coated so that the first surface 104a of the polarization plate 104 including the separator 104d is entered. This is because the separator 104d is peeled off in a later step and the first protection layer 116 does not remain on the first surface 104a of the polarization plate 104. However, there is a danger of damage such as peeling being applied to an end part of the first protection layer 116 together with the peeling of the separator 104d.

According to the method for manufacturing the display device 200 according to the present embodiment, it is possible to easily prevent the first protection layer 116 from entering the first surface 104a of the polarization plate 104. In this way, even if the separator 104d is peeled off after formation of the first protection layer 116, there is no influence on the first protection layer 116. Therefore, it is easy to prevent the first protection layer 116 from exposing the first surface 102a of the first substrate 102 and it is possible to prevent the first protection layer 116 from entering the first surface 104a of the polarization plate 104.

Next, the second protection layer 118 is arranged on the first surface 104a side of the polarization plate 104 to complete the display device 200 shown in FIG. 5. Here, since the first protection layer 116 is not arranged on the first surface 104a of the polarization plate 104, unevenness caused by the first protection layer 116 does not occur. Therefore, the second protection layer 118 can be favorably attached to the first surface 104a of the polarization plate 104.

According to the manufacturing method of the display device 200 according to the present embodiment, by arranging the oil repellent layer 122 along the end surface of the polarization plate 104, it is possible to easily provide the display device 200 with high reliability without deteriorating display quality.

### Third Embodiment

A third embodiment of a display device according to the present invention is explained. In the display device according to the first embodiment and the second embodiment, the oil repellent layer 122 is arranged at the end part of the polarization plate 104. The oil repellent property of the oil repellent layer 122 prevents the first protection layer 116 from running on the side surface of the polarization plate 104 and further entering the first surface 104a of the polarization plate 104.

Oil repellency may be provided to the surface of the polarization plate 104 instead of arranging the oil repellent layer 122 at the end part of the polarization plate 104. That is, if at least the first surface 104a of the polarization plate 104 has oil repellency, it is possible to prevent the first protection layer 116 from running on the side surface of the polarization plate 104 and further entering the first surface 104a of the polarization plate 104.

In order to provide an oil repellent layer to the surface of the polarization plate, fluorine coating can be performed by irradiating the surface of the polarization plate 104 with a plasma using a fluorine based gas, and thereby providing oil repellency.

The preferred embodiments of the present invention ere explained above. However, these are merely examples, and the technical scope of the present invention is not limited thereto. Various modifications are possible by persons skilled in the art without departing from the concept of the present invention. Therefore, it should be understood that such modifications naturally belong to the technical scope of the present invention.

What is claimed is:

1. A display device comprising:
a substrate including a display region arranged with a plurality of pixels, and a terminal region arranged with a plurality of connection terminals on a first surface of the substrate;
a plurality of wirings between the terminal region and the display region and transmitting a signal for controlling light emission of the plurality of pixels;
a polarization plate covering the display region;
an oil repellent layer along an end part of the polarization plate; and
a first protection layer covering the plurality of wirings for preventing exposure of the first surface of the substrate, the first protection layer arranged on the outer side of the polarization plate in a planar view in contact with an end part of the polarization plate.

2. The display device according to claim 1, wherein the oil repellent layer is arranged from an opposite side surface to a surface on the substrate side of the polarization plate to a side surface.

3. The display device according to claim 1, wherein the oil repellent layer is arranged on a side surface of the polarization plate.

4. The display device according to claim 1, wherein an end part of the oil repellent layer is arranged within a side surface of the polarization plate.

5. The display device according to claim 1, wherein the oil repellent layer is arranged on the outer side of the display region in a planar view.

6. The display device according to claim 1, wherein the oil repellent layer is either a silicone resin or a fluorine resin.

7. The display device according to claim 1, wherein the first protection layer is an acrylic resin.

8. The display device according to claim 1, further comprising a second protection layer above the polarization plate.

9. The display device according to claim 1, wherein the substrate has flexibility.

10. The display device according to claim 9, further comprising a third protection layer above a second surface side opposite to the first surface of the substrate.

11. The display device according to claim 10, wherein the substrate is further arranged with a bent region between the display region and the terminal region, and the third protection layer is arranged with a slit in the bent region in a planar view.
